(19) United States
(12) Patent Application Publication
(10) Pub. No.: US 2025/0185227 A1
(43) Pub. Date: Jun. 5, 2025

(54) KNOCKOUT SEAL INSTALLATION DEVICE

(71) Applicant: Nicholas Thousand, Clawson, MI (US)

(72) Inventor: Nicholas Thousand, Clawson, MI (US)

(21) Appl. No.: 18/526,077

(22) Filed: Dec. 1, 2023

(51) Int. Cl. H05K 13/00

(52) U.S. Cl. CPC H05K 13/0007

(57) ABSTRACT

A knockout seal installation device for installing a knockout seal in an open seal of an electrical box includes a tool that has a shaft which extends between a domed grip and a plate. The domed grip can be gripped by a user thereby facilitating the shaft to be directed toward an electrical box. A magnet is attached to the plate to magnetically engage a knockout seal thereby facilitating the knockout seal to be installed into an open seal in the electrical box.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to installation devices and more particularly pertains to a new installation device for installing a knockout seal in an open seal of an electrical box. The device includes a tool which has a shaft extending between a domed grip and a plate. The device includes a magnet which is recessed into the plate for magnetically engaging a knockout seal thereby facilitating the tool to be manipulated to install the knockout seal into an open seal in an electrical box.

### (2) Description of Related Art Including Information Disclosed Under 37 CFR 1.97 and 1.98

The prior art relates to installation devices including a variety of hand tools for installing knockout seals into open seals of electrical boxes which each includes pivoting jaws from gripping knockout seals and a knockout removal tool which includes a member that has strategically placed notches for removing knockout seals from electrical boxes. In no instance does the prior art disclose a knockout seal installation tool which has no moving parts and a magnet for magnetically engaging a knockout seal.

### BRIEF SUMMARY OF THE INVENTION

An embodiment of the disclosure meets the needs presented above by generally comprising a tool that has a shaft which extends between a domed grip and a plate. The domed grip can be gripped by a user thereby facilitating the shaft to be directed toward an electrical box. A magnet is attached to the plate to magnetically engage a knockout seal thereby facilitating the knockout seal to be installed into an open seal in the electrical box.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a top perspective view of a knockout seal installation device according to an embodiment of the disclosure.

FIG. 2 is a bottom perspective view of an embodiment of the disclosure.

FIG. 3 is a front phantom view of an embodiment of the disclosure.

FIG. 4 is a bottom view of an embodiment of the disclosure.

FIG. 5 is a cross sectional view taken along line 5-5 of FIG. 4 of an embodiment of the disclosure.

FIG. 6 is a perspective in-use view of an embodiment of the disclosure showing a knockout seal being magnetically retained on a tool.

FIG. 7 is a perspective in-use view of an embodiment of the disclosure showing a knockout seal being installed into an open seal of an electrical box.

### DETAILED DESCRIPTION OF THE INVENTION

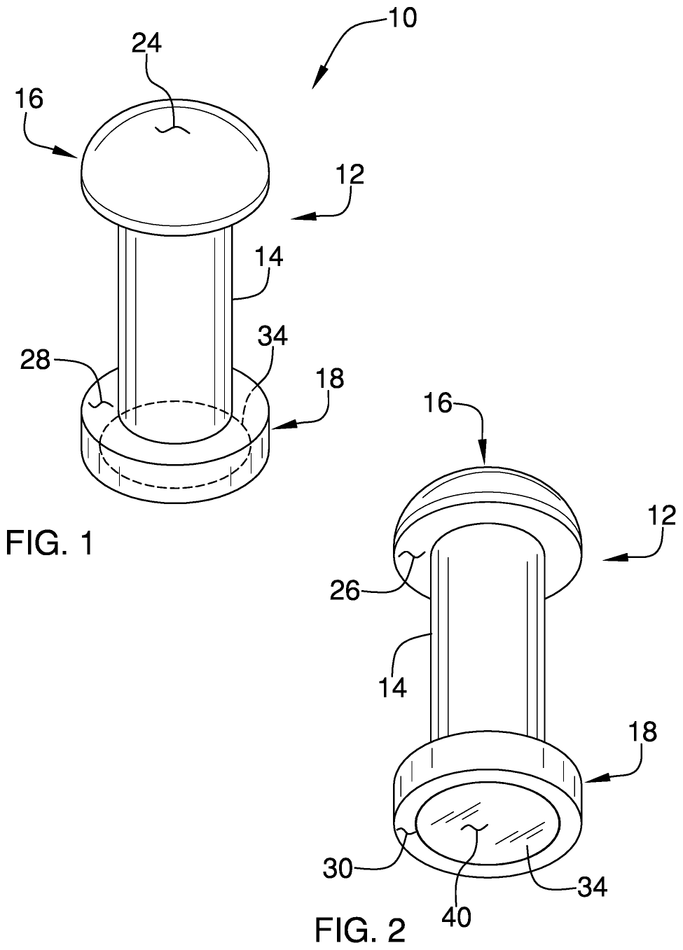

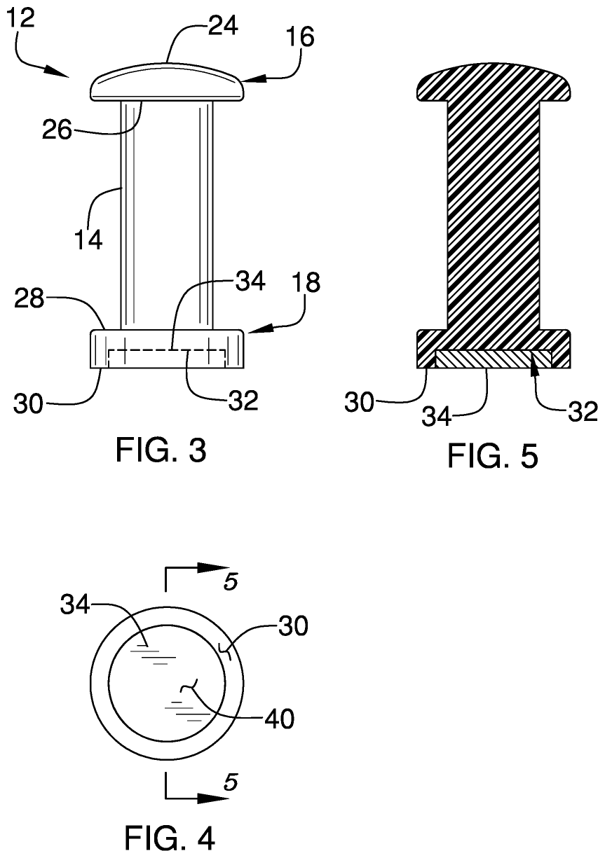

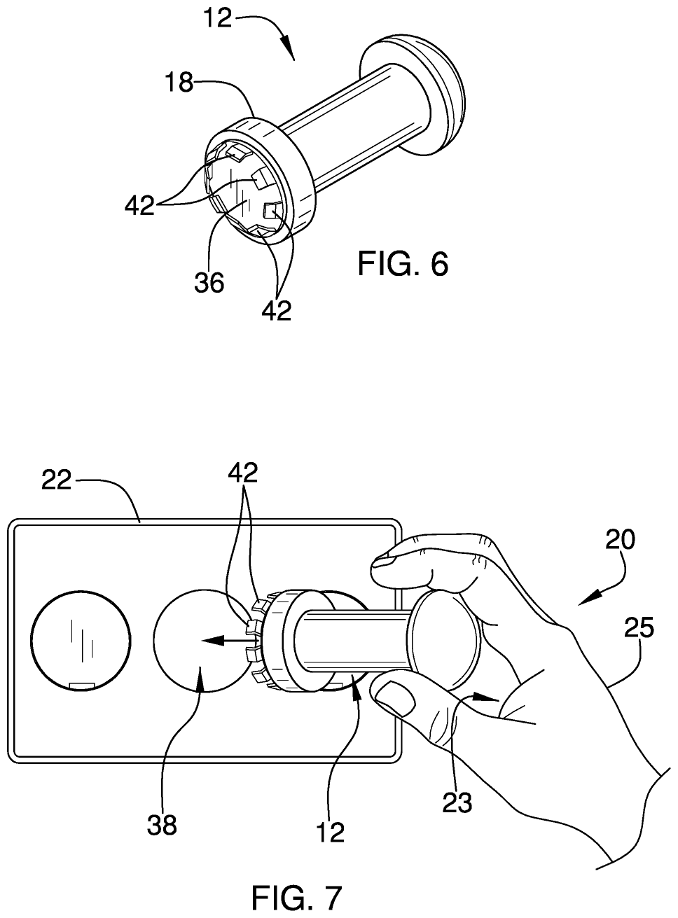

With reference now to the drawings, and in particular to FIGS. 1 through 7 thereof, a new installation device embodying the principles and concepts of an embodiment of the disclosure and generally designated by the reference numeral 10 will be described.

As best illustrated in FIGS. 1 through 7, the knockout seal installation device 10 generally comprises a tool 12 that has a shaft 14 extending between a domed grip 16 and a plate 18. The domed grip 16 can be gripped by a user 20 thereby facilitating the shaft 14 to be directed toward an electrical box 22. The electrical box 22 may be a light switch box, a junction box, a circuit breaker box or any other type of electrical box commonly employed in electrical systems of either residential buildings or commercial buildings. The domed grip 16 has a top surface 24 and a bottom surface 26; the top surface 24 is concavely arcuate with respect to the bottom surface 26 and the bottom surface 26 is planar such that the domed grip 16 defines a dome. In this way the top surface 24 of the domed grip 16 can fit comfortably into the palm 23 of the user's hand 25.

The plate 18 has an upper surface 28 and a lower surface 30 and the shaft 14 extends between the bottom surface 26 of the domed grip 16 and the upper surface 28 of the plate 18; The upper surface 28 of the plate 18 lies on a plane is oriented parallel to the bottom surface 26 of the domed grip 16. Additionally, the plate 18 has a well 32 extending into the lower surface 30 of the plate 18 and the well 32 is centrally located on the lower surface 30.

A magnet 34 is attached to the plate 18 to magnetically engage a knockout seal 36 thereby facilitating the knockout seal 36 to be installed into an open seal 38 in the electrical box 22. The magnet 34 is positioned in the well 32 in the lower surface 30 of the plate 18 having the magnet 34 completely filling the well 32. Furthermore, the magnet 34 has an exposed surface 40 which is aligned with the lower surface 30 of the plate 18. In this way the knockout seal 36 can lie flush against the exposed surface 40 of the magnet 34 and the lower surface 30 of the plate 18. Additionally, the knockout seal 36 may be a metallic knockout seal which is employed in metallic electrical boxes.

In use, the knockout seal 36 is positioned against the exposed surface 40 of the magnet 34 such that fingers 42 on the knockout seal 36 are directed away from the magnet 34. The domed grip 16 is gripped and the tool 12 is manipulated to direct the fingers 42 of the knockout seal 36 into an open seal 38 in the electrical box 22. The domed grip 16 is urged toward the electrical box 22 there urging the knockout seal 36 into the open seal 38 until the knockout seal 36 is fully seated in the open seal 38. In this way the knockout seal 36 can be installed with minimal risk of injuries to fingers and hands as can commonly occur when installing knockout seals by hand.

With respect to the above description then, it is to be realized that the optimum dimensional relationships for the parts of an embodiment enabled by the disclosure, to include variations in size, materials, shape, form, function and manner of operation, device and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A knockout seal installation device for installing a knockout seal in an electrical junction box, said device comprising:
a tool having a shaft extending between a domed grip and a plate wherein said domed grip is configured to be gripped by a user thereby facilitating said shaft to be directed toward an electrical box; and
a magnet being attached to said plate wherein said magnet is configured to magnetically engage a knockout seal thereby facilitating the knockout seal to be installed into an open seal in the electrical box.

2. The device according to claim 1, wherein:
said domed grip has a top surface and a bottom surface;
said top surface is concavely arcuate with respect to said bottom surface;
said bottom surface is planar;
said plate has an upper surface and a lower surface; and
said shaft extends between said bottom surface of said domed grip and said upper surface of said plate such that said upper surface of said plate lies on a plane being oriented parallel to said bottom surface of said domed grip.

3. The device according to claim 1, wherein:
said plate has a well extending into said lower surface of said plate; and
said well is centrally located on said lower surface.

4. The device according to claim 3, wherein said magnet is positioned in said well in said lower surface of said plate having said magnet completely filling said well.

5. The device according to claim 4, wherein said magnet having an exposed surface being aligned with said lower surface of said plate.

6. A knockout seal installation device for installing a knockout seal in an electrical junction box, said device comprising:
a tool having a shaft extending between a domed grip and a plate wherein said domed grip is configured to be gripped by a user thereby facilitating said shaft to be directed toward an electrical box, said domed grip having a top surface and a bottom surface, said top surface being concavely arcuate with respect to said bottom surface, said bottom surface being planar, said plate having an upper surface and a lower surface, said shaft extending between said bottom surface of said domed grip and said upper surface of said plate such that said upper surface of said plate lies on a plane being oriented parallel to said bottom surface of said domed grip, said plate having a well extending into said lower surface of said plate, said well being centrally located on said lower surface; and
a magnet being attached to said plate wherein said magnet is configured to magnetically engage a knockout seal thereby facilitating the knockout seal to be installed into an open seal in the electrical box, said magnet being positioned in said well in said lower surface of said plate having said magnet completely filling said well, said magnet having an exposed surface being aligned with said lower surface of said plate.

7. A method of installing a knockout seal in an open seal of an electrical box, the steps of the method comprising:
gripping a domed grip of a tool, said tool having a shaft extending between said domed grip and a plate, said plate having a magnet being recessed into said plate;
placing a knockout seal on said plate such that said magnet magnetically retains said knockout seal on said plate;
manipulating said tool to direct said knockout seal toward an open seal in an electrical box; and
pushing said domed grip to urge said knockout seal into said open seal in said electrical box until said knockout seal is seated into said open seal.
